(19) United States
(12) Patent Application Publication
(10) Pub. No.: US 2007/0196992 A1
(43) Pub. Date: Aug. 23, 2007

(54) In-situ doped silicon germanium and silicon carbide source drain region for strained silicon CMOS transistors

(75) Inventors: Mo Hong Xiang, Shanghai (CN); John Chen, Shanghai (CN); Bei Zhu, Shanghai (CN); Dai Wei Gao, Shanghai (CN); Hanming Wu, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing Int'l (Shanghai) Corporation, Shanghai (CN)

(21) Appl. No.: 11/442,009

(22) Filed: May 26, 2006

Related U.S. Application Data
(63) Continuation of application No. 11/244,255, filed on Oct. 4, 2005, now abandoned.

(30) Foreign Application Priority Data
Sep. 28, 2005 (CN) 200510030308.1

(51) Int. Cl. H01L 21/331; H01L 21/8222

(52) U.S. Cl. 438/320

(57) ABSTRACT

A method for forming a semiconductor integrated circuit device, e.g., MOS, CMOS. The method includes providing a semiconductor substrate, e.g., silicon substrate, silicon on insulator. The method includes forming a dielectric layer (e.g., silicon dioxide, silicon nitride, silicon oxynitride) overlying the semiconductor substrate. The method also includes forming a gate layer (e.g., polysilicon) overlying the dielectric layer. The method patterns the gate layer to form a gate structure including edges. The method includes forming a dielectric layer overlying the gate structure to protect the gate structure including the edges. In a specific embodiment, sidewall spacers are formed using portions of the dielectric layer. The method etches a source region and a drain region adjacent to the gate structure using the dielectric layer as a protective layer. In a preferred embodiment, the method deposits using selective epi growth of silicon germanium material into the source region and the drain region to fill the etched source region and the etched drain region and simultaneously introduces a dopant impurity species into the silicon germanium material during a portion of the time associated with the depositing of the silicon germanium material to dope the silicon germanium material during the portion of the time associated with the depositing of the silicon germanium material. In a specific embodiment, the method also includes causing a channel region between the source region and the drain region to be strained in compressive mode from at least the silicon germanium material formed in the source region and the drain region.

### CROSS-REFERENCES TO RELATED APPLICATIONS

This Continuation Application claims priority to Chinese Application No. 200510030308.1, filed Sep. 28, 2005 and U.S. patent application Ser. No. 11/244,255 (Attorney Docket No. 021653-010200US); filed Oct. 4, 2005 commonly assigned, and of which is incorporated by reference for all purposes.

### BACKGROUND OF THE INVENTION

The present invention is directed to integrated circuits and their processing for the manufacture of semiconductor devices. More particularly, the invention provides a method and structures for manufacturing MOS devices using strained silicon structures for advanced CMOS integrated circuit devices. But it would be recognized that the invention has a much broader range of applicability.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials.

An example of such a process is the manufacture of MOS devices itself. Such device has traditionally became smaller and smaller and produced faster switching speeds. Although there have been significant improvements, such device designs still have many limitations. As merely an example, these designs must become smaller and smaller but still provide clear signals for switching, which become more difficult as the device becomes smaller. Additionally, these designs are often difficult to manufacture and generally require complex manufacturing processes and structures. These and other limitations will be described in further detail throughout the present specification and more particularly below.

From the above, it is seen that an improved technique for processing semiconductor devices is desired.

### BRIEF SUMMARY OF THE INVENTION

According to the present invention, techniques for processing integrated circuits for the manufacture of semiconductor devices are provided. More particularly, the invention provides a method and structures for manufacturing MOS devices using strained silicon structures for CMOS advanced integrated circuit devices. But it would be recognized that the invention has a much broader range of applicability.

In a specific embodiment, the present invention provides a method for forming a semiconductor integrated circuit device, e.g., MOS, CMOS. The method includes providing a semiconductor substrate, e.g., silicon substrate, silicon on insulator. The method includes forming a dielectric layer (e.g., silicon dioxide, silicon nitride, silicon oxynitride) overlying the semiconductor substrate. The method also includes forming a gate layer (e.g., polysilicon) overlying the dielectric layer. The method patterns the gate layer to form a gate structure including edges. The method includes forming a dielectric layer overlying the gate structure to protect the gate structure including the edges. In a specific embodiment, sidewall spacers are formed using portions of the dielectric layer. The method etches a source region and a drain region adjacent to the gate structure using the dielectric layer as a protective layer. In a preferred embodiment, the method deposits using selective epi growth of silicon germanium material into the source region and the drain region to fill the etched source region and the etched drain region and simultaneously introduces a dopant impurity species into the silicon germanium material during a portion of the time associated with the depositing of the silicon germanium material to dope the silicon germanium material during the portion of the time associated with the depositing of the silicon germanium material. In a specific embodiment, the method also includes causing a channel region between the source region and the drain region to be strained in compressive mode from at least the silicon germanium material formed in the source region and the drain region.

In a specific embodiment, the present invention provides a method for forming a semiconductor integrated circuit device. The method includes providing a semiconductor substrate, which is characterized by a first lattice constant. The method includes forming a dielectric layer overlying the semiconductor substrate and forming a gate layer overlying the dielectric layer. The method includes patterning the gate layer to form a gate structure including edges and forming a dielectric layer overlying the gate structure to protect the gate structure including the edges. The method etches a source region and a drain region adjacent to the gate structure using the dielectric layer as a protective layer and deposits using selective epi growth material into the source region and the drain region to fill the etched source region and the etched drain region. Preferably, the method simultaneously introduces a dopant impurity species into the fill material during a portion of the time associated with the depositing of the fill material to dope the fill material during the portion of the time associated with the depositing of the fill material, which is characterized by a second lattice constant. The method also causes a channel region between the source region and the drain region to be strained, the strained channel region being associated with at least a difference between the first lattice constant of the semiconductor substrate and the second lattice constant of the fill material formed in the source region and the drain region.

Many benefits are achieved by way of the present invention over conventional techniques. For example, the present technique provides an easy to use process that relies upon conventional technology. In some embodiments, the method provides higher device yields in dies per wafer. Additionally, the method provides a process that is compatible with conventional process technology without substantial modifications to conventional equipment and processes. Preferably, the invention provides for an improved process integration for design rules of 65 nanometers and less or 90 nanometers and less. The invention also provides for an improved way of forming deposited source/drain regions that are not subject to time consuming diffusion techniques of the prior art. Additionally, the invention provides for increased mobility of holes using a strained silicon structure for CMOS devices. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified cross-sectional view diagram of a CMOS device according to an embodiment of the present invention.

FIG. 2 is a simplified flow diagram illustrating a method for fabricating a CMOS device according to an embodiment of the present invention.

FIGS. 3 through 6 are simplified cross-sectional view diagrams illustrating a method for fabricating a CMOS device according to an embodiment of the present invention.

FIG. 7 is a simplified cross-sectional view diagram of an alternative CMOS device according to an alternative embodiment of the present invention.

### DETAILED DESCRIPTION OF THE INVENTION

According to the present invention, techniques for processing integrated circuits for the manufacture of semiconductor devices are provided. More particularly, the invention provides a method and structures for manufacturing MOS devices using strained silicon structures for CMOS advanced integrated circuit devices. But it would be recognized that the invention has a much broader range of applicability.

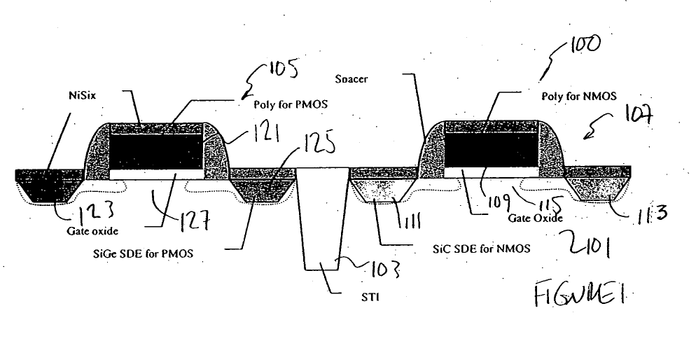

FIG. 1 is a simplified cross-sectional view diagram of a CMOS device 100 according to an embodiment of the present invention. This diagram is merely an example, which should not unduly limit the scope of the claims herein. One of ordinary skill in the art would recognize many variations, alternatives, and modifications. As shown, the CMOS device includes an NMOS device 107 comprising a gate region 109, a source region 111, a drain region 113 and an NMOS channel region 115 formed between the source region and drain region. Preferably, the channel region has width of less than 90 microns in a preferred embodiment. Of course, there can be other variations, modifications, and alternatives.

A silicon carbide material is formed within the source region 111 and is formed within the drain region 113. That is, the silicon carbide material is epitaxially grown within etched regions of the source and drain regions to form a multilayered structure. The silicon carbide material is preferably doped using an N type impurity. In a specific embodiment, the impurity is phosphorous and has a concentration ranging from about 1×10¹⁹ to about 1×10²⁰ atoms/cm³. Other N type impurities such as arsenic at a suitable concentration can also used depending on the application. The silicon carbide material causes the channel region to be in a tensile mode. The silicon carbide material has a lattice constant that is less than the lattice constant for single crystal silicon. Since the lattice constant is smaller for silicon carbide, it causes the NMOS channel region to be in a tensile mode. The channel region is longer than for single crystal silicon by about 0.7-0.8 percent in a specific embodiment. The NMOS device is formed in a P-type well region. Of course, there can be other variations, modifications, and alternatives.

The CMOS device also has a PMOS device 105 comprising a gate region 121, a source region 123, and a drain region 125. The PMOS device has a PMOS channel region 127 formed between the source region and the drain region. Preferably, the channel region has width of less than 90 microns in a preferred embodiment. The PMOS device is also formed in N-type well regions. The N-type well region is preferably doped using an N type impurity. Of course, there can be other variations, modifications, and alternatives.

A silicon germanium material is formed within the source region and within the drain region. That is, the silicon germanium material is epitaxially grown within etched regions of the source and drain regions to form a multilayered structure. The silicon germanium material is preferably doped using a P type impurity. In a specific embodiment, the impurity is boron and has a concentration ranging from about 1×10¹⁹ to about 1×10²⁰ atoms/cm³. The silicon germanium material causes the channel region to be in a compressive mode. The silicon germanium material has a lattice constant that is larger than the lattice constant for single crystal silicon. Since the lattice constant is larger for silicon germanium, it tends to cause the PMOS channel region to be in a compressive mode. The channel region is shorter than for single crystal silicon by about 0.7-0.8 percent in a specific embodiment.

In a preferred embodiment, the source/drain regions have been in-situ doped concurrent with the formation of the silicon germanium material. In a specific embodiment, the present source/drain regions have been provided using deposition of selective epi growth of silicon germanium material into the source region and the drain region to fill the etched source region and the etched drain region and simultaneously introducing a dopant impurity species into the silicon germanium material during a portion of the time associated with the depositing of the silicon germanium material to dope the silicon germanium material during the portion of the time associated with the depositing of the silicon germanium material. In a preferred embodiment, the portion of time is associated with an entirety of the deposition time or substantially an entirety of the deposition time. Depending upon the embodiment, the source/drain regions have been provided using certain predetermined conditions.

As merely an example, the dopant impurity species in the source/drain regions is provided in-situ at a temperature of about 700 Degrees Celsius. The dopant impurity species comprise boron bearing impurities, which have a concentration ranging 1×10¹⁹ to 5×10²⁰ atoms/cm³ according to a specific embodiment. In a specific embodiment, the dopant impurity species comprise a boron species derived from B₂H₆, which is a P−type impurity. In certain embodiments, the source/drain regions further include a P+type. implant in the silicon germanium material in the source region and the drain region. Depending upon the embodiment, the source/drain regions have also been subjected to a rapid thermal anneal of the silicon germanium material at a temperature ranging from about 1000 to about 1200 Celsius. Additionally, the selective epi growth occurs only on exposed crystalline silicon surfaces using silicon germanium species, e.g., SiH₄ bearing species and an GeH₄ being species. Such silicon germanium species may be combined with an HCl species and H₂ species in preferred embodiments. Of course, one of ordinary skill in the art would recognize many variations, modifications, and alternatives.

As further shown, the device has isolation regions 103, which are formed between active transistor devices, such as the MOS devices. The isolation regions are preferably made using shallow trench isolation techniques. Such techniques often use patterning, etching, and filling the trench with a dielectric material such as silicon dioxide or like material. Of course, one of ordinary skill in the art would recognize other variations, modifications, and alternatives. Further details of a method for fabricating the CMOS device can be found throughout the present specification and more particularly below.

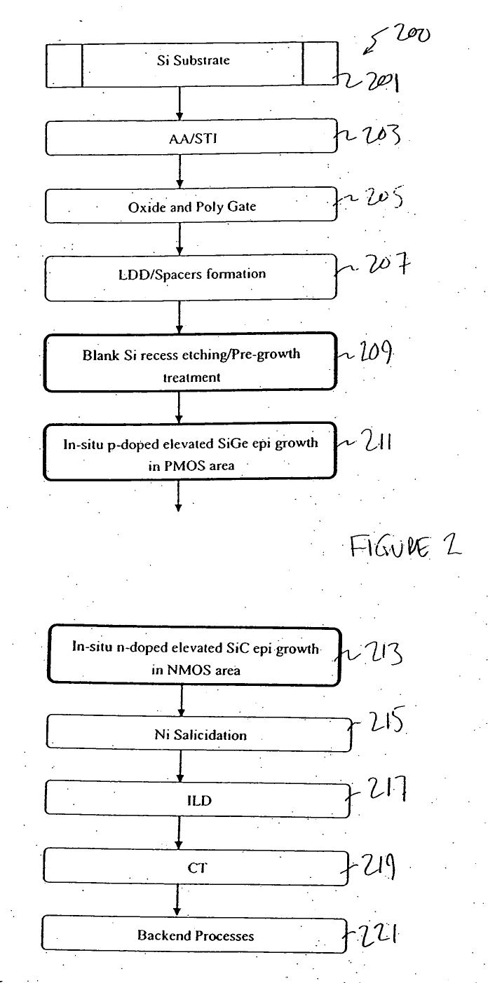

Referring to FIG. 2 a method 200 for fabricating a CMOS integrated circuit device according to an embodiment of the present invention may be outlined as follows:

1. Provide a semiconductor substrate (step 201), e.g., silicon wafer, silicon on insulator;

2. Form shallow trench isolation regions (step 203);

3. Form a gate dielectric layer (step 205) overlying the surface of the substrate;

4. Form a gate layer overlying the semiconductor substrate;

5. Pattern the gate layer to form an NMOS gate structure including edges and pattern a PMOS gate structure including edges;

6. Form lightly doped drain regions and sidewall spacers (step 207) on edges of patterned gate layer;

7. Form a dielectric layer overlying the NMOS gate structure to protect the NMOS gate structure including the edges and overlying the PMOS gate structure to protect the PMOS gate structure including the edges;

8. Simultaneously etch a first source region and a first drain region adjacent to the NMOS gate structure and etch a second source region and a second drain region adjacent to the PMOS gate structure using the dielectric layer as a protective layer (step 209);

9. Pretreat etched source/drain regions;

10. Mask NMOS regions;

11. Deposit silicon germanium material into the first source region and the first drain region to cause a channel region between the first source region and the first drain region of the PMOS gate structure to be strained in a compressive mode (step 211);

12. Simultaneously introduce a dopant impurity species into the silicon germanium material during a portion of the time associated with the depositing of the silicon germanium material to dope the silicon germanium material during the portion of the time associated with the depositing of the silicon germanium material

13. Strip Mask from NMOS regions;

14. Mask PMOS regions;

15. Deposit silicon carbide material into the second source region and second drain region to cause the channel region between the second source region and the second drain region of the NMOS gate structure to be strained in a tensile mode (step 213);

16. Simultaneously introduce a dopant impurity species into the silicon carbide material during a portion of the time associated with the depositing of the silicon carbide material to dope the silicon carbide material during the portion of the time associated with the depositing of the silicon carbide material;

17. Form silicide layer overlying gate layer and source/drain regions (step 215);

18. Form interlayer dielectric layer overlying NMOS and PMOS transistor devices (step 217);

19. Perform electrical contacts (step 219);

20. Perform back end processes (step 221); and

21. Perform other steps, as desired.

The above sequence of steps provides a method according to an embodiment of the present invention. As shown, the method uses a combination of steps including a way of forming a CMOS integrated circuit device. In a preferred embodiment, the method provides an in-situ doping process when filling the silicon germanium material into recessed regions corresponding to source/drain regions for a PMOS device, and an in-situ doping process when filling the silicon carbide material into recessed regions corresponding to source/drain regions for a NMOS device. Other alternatives can also be provided where steps are added, one or more steps are removed, or one or more steps are provided in a different sequence without departing from the scope of the claims herein. Further details of the present method can be found throughout the present specification and more particularly below.

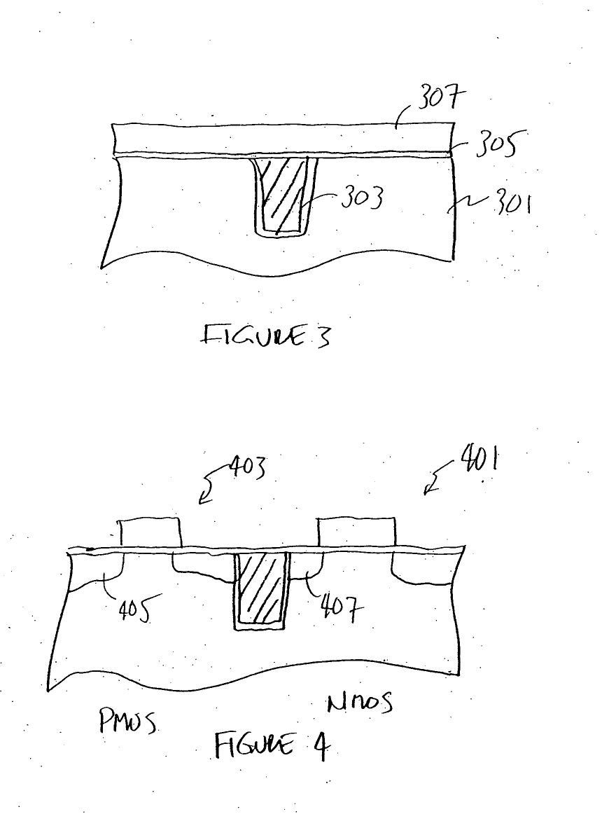

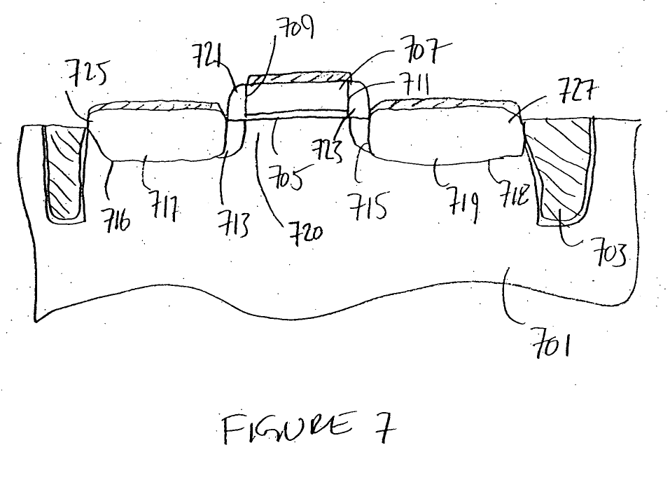

FIGS. 3-6 are simplified diagrams illustrating a method for fabricating a CMOS device according to an embodiment of the present invention. These diagrams are merely examples, which should not unduly limit the scope of the claims herein. One of ordinary skill in the art would recognize many variations, alternatives, and modifications. As shown, the method provides a semiconductor substrate 301, e.g., silicon wafer, silicon on insulator. The semiconductor substrate is single crystalline silicon. The silicon is oriented in the (100) direction on the face of the wafer. Of course, there can be other variations, modifications, and alternatives. Preferably, the method forms isolation regions within the substrate. In a specific embodiment, the method forms a shallow trench isolation region or regions 303 within a portion of the semiconductor substrate. The shallow trench isolation regions are formed using patterning, etching, and deposition of a dielectric fill material within the trench region. The dielectric fill material is often oxide or a combination of oxide and nitride depending upon the specific embodiment. The isolation regions are used to isolate active regions within the semiconductor substrate.

The method forms a gate dielectric layer 305 overlying the surface of the substrate. Preferably, the gate dielectric layer is oxide or silicon oxynitride depending upon the embodiment. The gate dielectric layer is preferably having a thickness range from 10 to 20 nanometers and less depending upon the specific embodiment. The method forms a gate layer 307 overlying the semiconductor substrate. The gate layer is preferably polysilicon that has been doped using either in-situ doping or ex-situ implantation techniques. The impurity for doping is often boron, arsenic, or phosphorus having a concentration ranging from about 1×10¹⁹ to about 1×10²⁰ atoms/cm³. Of course, one of ordinary skill in the art would recognize many variations, modifications, and alternatives.

Referring to FIG. 4, the method patterns the gate layer to form an NMOS gate structure 401 including edges and patterns a PMOS gate structure 403 including edges. The method forms lightly doped drain regions 405, 407, and optionally sidewall spacers on edges of patterned gate layer. Depending upon the embodiment, there may also be no sidewall spacers. The lightly doped drain regions are often formed using implantation techniques. For the PMOS device, the lightly doped drain region uses Boron or BF₂ impurity having a concentration ranging from about 1×10¹⁸ to about 1×10¹⁹ atoms/cm³. For the NMOS device, the lightly doped drain region uses arsenic impurity having a concentration ranging from about 1×10¹⁸ to about 1×10¹⁹ atoms/cm³. The method forms a dielectric layer overlying the NMOS gate structure to protect the NMOS gate structure including the edges. The method also forms a dielectric protective layer overlying the PMOS gate structure to protect the PMOS gate structure including the edges. Preferably, the dielectric protective layer is the same layer for PMOS and NMOS devices. Alternatively, another suitable material can be used to protect the NMOS and PMOS gate structures, including lightly doped drain regions.

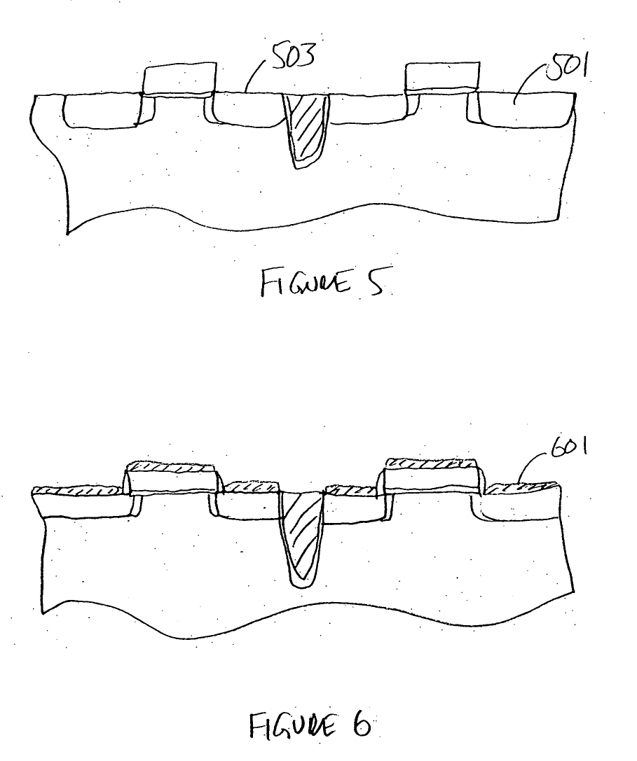

Referring to FIG. 5, the method simultaneously etches a first source region and a first drain region adjacent to the NMOS gate structure 501 and etches a second source region and a second drain region adjacent to the PMOS gate structure 503 using the dielectric layer as a protective layer. The method uses reactive ion etching techniques including a SF₆ or CF₄ bearing species and plasma environment. In a preferred embodiment, the method performs a pre-treatment process on etched source/drain regions, which preserves the etched interfaces to maintain substantially high quality silicon bearing material. According to a specific embodiment, the each of the etched regions has a depth of ranging from about 100 Angstroms (Å) to about 1000 Å and a length of about 0.1 um to about 10 um, and a width of about 0.1 um to about 10 um for a 90 nanometer channel length. Each of the etched regions has a depth of ranging from about 100 Å to about 1,000 A and a length of about 0.1 um to about 10 um, and a width of about 0.1 um to about 10 um for a 65 nanometer channel length according to an alternative specific embodiment.

The method masks NMOS regions, while exposing the PMOS etched regions. The method deposits silicon germanium material into the first source region and the first drain region to cause a channel region between the first source region and the first drain region of the PMOS gate structure to be strained in a compressive mode. The silicon germanium is epitaxially deposited using in-situ doping techniques. That is, impurities such as boron are introduced while the silicon germanium material grows. A concentration ranges from about 1×10¹⁹ to about 1×10²⁰ atoms/cm³ of boron according to a specific embodiment. Of course, there can be other variations, modifications, and alternatives.

The method strips the mask from NMOS regions. The method masks PMOS regions, while exposing the NMOS etched regions. The method deposits silicon carbide material into the second source region and second drain region to cause the NMOS channel region between the second source region and the second drain region of the NMOS gate structure to be strained in a tensile mode. The silicon carbide is epitaxially deposited using in-situ doping techniques. That is, impurities such as phosphorous (P) or arsenic (As) are introduced while the silicon carbide material grows. A concentration ranges from about 1×10¹⁹ to about 1×10²⁰ atoms/cm³ of the above impurities according to a specific embodiment. Of course, there can be other variations, modifications, and alternatives.

To finish the device according to an embodiment of the present invention, the method forms a silicide layer 601 overlying gate layer and source/drain regions. Preferably, the silicide layer is a nickel bearing layer such as nickel silicide overlying the exposed source/drain regions and upper surface of the patterned gate layer. Other types of silicide layers can also be used. Such silicide layers include titanium silicide, tungsten silicide, nickel silicide, and the like. The method forms an interlayer dielectric layer overlying NMOS and PMOS transistor devices. The method then forms electrical contacts. Other steps include performing a back end processes and other steps, as desired.

The above sequence of steps provides a method according to an embodiment of the present invention. As shown, the method uses a combination of steps including a way of forming a CMOS integrated circuit device. In a preferred embodiment, the method provides an in-situ doping process when filling the silicon germanium material into recessed regions corresponding to source/drain regions of a PMOS device and an in-situ doping process when filling the silicon carbide material into recessed regions corresponding to source/drain regions of a NMOS device. Other alternatives can also be provided where steps are added, one or more steps are removed, or one or more steps are provided in a different sequence without departing from the scope of the claims herein.

A method for fabricating a CMOS integrated circuit device according to an embodiment of the present invention may be outlined as follows:

1. Provide a semiconductor substrate, e.g., silicon wafer, silicon on insulator;

2. Form a dielectric layer (e.g., gate oxide or nitride) overlying the semiconductor substrate;

3. Form a gate layer (e.g., polysilicon, metal) overlying the dielectric layer;

4. Pattern the gate layer to form a gate structure including edges (e.g., a plurality of sides or edges);

5. Form a dielectric layer or multi-layers overlying the gate structure to protect the gate structure including the edges, wherein the dielectric layer being less than 1000 A;

6. Etch a source region and a drain region adjacent to the gate structure using the dielectric layer as a protective layer;

7. Deposit silicon germanium material into the source region and the drain region to fill the etched source region and the etched drain region;

8. Simultaneously introduce a dopant impurity species into the silicon germanium material during a portion of the time associated with the depositing of the silicon germanium material to dope the silicon germanium material during the portion of the time associated with the depositing of the silicon germanium material;

9. Cause a channel region between the source region and the drain region to be strained in compressive mode from at least the silicon germanium material formed in the source region and the drain region, wherein the channel region is about the same width as the patterned gate layer;

10. Form sidewall spacers overlying the patterned gate layer; and

11. Perform other steps, as desired.

The above sequence of steps provides a method according to an embodiment of the present invention. As shown, the method uses a combination of steps including a way of forming a CMOS integrated circuit device. In a preferred embodiment, the method provides an in-situ doping process when filling the silicon germanium material into recessed regions corresponding to source/drain regions. Other alternatives can also be provided where steps are added, one or more steps are removed, or one or more steps are provided in a different sequence without departing from the scope of the claims herein.

FIG. 7 is a simplified cross-sectional view diagram of an alternative MOS device according to an alternative embodiment of the present invention. This diagram is merely an example, which should not unduly limit the scope of the claims herein. One of ordinary skill in the art would recognize many variations, alternatives, and modifications. As shown, the device is a PMOS integrated circuit device. Alternatively, the device may also be NMOS or the like. The device has a semiconductor substrate 701 (e.g., silicon, silicon on insulator) comprising a surface region and an isolation region 703 (e.g., trench isolation) formed within the semiconductor substrate. A gate dielectric layer 705 is formed overlying the surface region of the semiconductor substrate. A PMOS gate layer 707 is formed overlying a portion of the surface region. The gate layer is preferably doped polysilicon that has been crystallized according to a specific embodiment. The doping is often an impurity such as boron having a concentration ranging from about 1×10¹⁹ to about 1×10²⁰ atoms/cm³ depending upon the specific embodiment.

The PMOS gate layer includes a first edge 709 and a second edge 711. The device has a first lightly doped region 713 formed within a vicinity of the first edge and a second lightly doped region 715 formed within a vicinity of the second edge. The device also has a first sidewall spacer 721 formed on the first edge and on a portion of the first lightly doped region and a second sidewall spacer 723 formed on the second edge and on a portion of the second lightly doped region. A first etched region of semiconductor substrate is formed adjacent to the first sidewall spacer and a second etched region of semiconductor substrate is formed adjacent to the second sidewall spacer. The device has a first silicon germanium material 717 formed within the first etched region 716 to form a first source/drain region and a second silicon germanium material 719 formed within the second etched region 718 to form a second source/drain region. The silicon germanium layer has been grown using an epitaxial process. The silicon germanium is also doped using an impurity such as boron having a concentration ranging from about 1×10¹⁹ to about 1×10²⁰ depending upon the specific embodiment.

A PMOS channel region 720 is formed between the first silicon germanium material and the second silicon germanium layer. Preferably, the first silicon germanium material comprises a first surface 725 that has a height above the surface region and the second silicon germanium material comprises a second surface 727 that has a height above the surface region. The device has a silicide layer overlying gate layer and source/drain regions. Preferably, the silicide layer is a nickel bearing layer such as nickel silicide overlying the exposed source/drain regions and upper surface of the patterned gate layer, as shown. Of course, there can be other variations, modifications, and alternatives.

In a preferred embodiment, the source/drain regions have been in-situ doped concurrent with the formation of the silicon germanium material. In a specific embodiment, the present source/drain regions have been provided using deposition of selective epi growth of silicon germanium material into the source region and the drain region to fill the etched source region and the etched drain region and simultaneously introducing a dopant impurity species into the silicon germanium material during a portion of the time associated with the depositing of the silicon germanium material to dope the silicon germanium material during the portion of the time associated with the depositing of the silicon germanium material. In a preferred embodiment, the portion of time is associated with an entirety of the deposition time or substantially an entirety of the deposition time. Depending upon the embodiment, the source/drain regions have been provided using certain predetermined conditions.

As merely an example, the dopant impurity species in the source/drain regions is provided in-situ at a temperature of about 700 Degrees Celsius. The dopant impurity species comprise boron bearing impurities, which have a concentration ranging 1×10¹⁹ to 5×10²⁰ atoms/cm³ according to a specific embodiment. In a specific embodiment, the dopant impurity species comprise a boron species derived from B₂H₆, which is a P−type impurity. In certain embodiments, the source/drain regions further include a P+type implant in the silicon germanium material in the source region and the drain region. Depending upon the embodiment, the source/drain regions have also been subjected to a rapid thermal anneal of the silicon germanium material at a temperature ranging from about 1000 to about 1200 Celsius. Additionally, the selective epi growth occurs only on exposed crystalline silicon surfaces using silicon germanium species, e.g., SiH₄ bearing species and an GeH₄ being species. Such silicon germanium species may be combined with an HCl species and H₂ species in preferred embodiments. Of course, one of ordinary skill in the art would recognize many variations, modifications, and alternatives.

Although the above has been described in terms of specific embodiments, there can be other variations, modifications, and alternatives. For example, the present techniques provides for in-situ doping of the source/drain regions of a silicon germanium fill material for a PMOS device. The invention can also be applied to in-situ doping of the source/drain regions of a silicon carbide material for a NMOS device or the like. Alternatively, there can be in-situ doping of other features of the invention within the scope of the claims herein. It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for forming a semiconductor integrated circuit device comprising:
providing a semiconductor substrate;
forming a dielectric layer overlying the semiconductor substrate;
forming a gate layer overlying the dielectric layer;
patterning the gate layer to form a gate structure including edges;
forming a dielectric layer overlying the gate structure to protect the gate structure including the edges;
etching a source region and a drain region adjacent to the gate structure using the dielectric layer as a protective layer;
depositing using selective epi growth of a silicon germanium material into the source region and the drain region to fill the etched source region and the etched drain region;
simultaneously introducing a dopant impurity species into the silicon germanium material during a portion of the time associated with the depositing of the silicon germanium-material to dope the silicon germanium material during the portion of the time associated with the depositing of the silicon germanium material; and
causing a channel region between the source region and the drain region to be strained in compressive mode from at least the silicon germanium material formed in the source region and the drain region.

2. The method of claim 1 wherein the dielectric layer has a thickness that is less than 300 Angstroms.

3. The method of claim 1 wherein the channel region has a length of a width of the gate structure.

4. The method of claim 1 wherein the semiconductor substrate is essentially silicon material.

5. The method of claim 1 wherein the silicon germanium material is single crystalline.

6. The method of claim 1 wherein the silicon germanium has a ratio of silicon/germanium of 10:90 to 20:90.

7. The method of claim 1 further comprising forming a spacer layer overlying the semiconductor substrate including silicon germanium, gate structure, and edges.

8. The method of claim 7 further comprising anisotropic etching the spacer layer to form sidewall spacers on edges of the gate layer.

9. The method of claim 1 wherein the depositing is provided using an epitaxial reactor.

10. The method of claim 1 wherein the compressive mode increases a mobility of holes in the channel region.

11. The method of claim 1 wherein the dopant impurity species is provided in-situ at a temperature of about 700 Degrees Celsius.

12. The method of claim 1 wherein the dopant impurity species comprise boron bearing impurities, the boron impurities having a concentration ranging 1×10¹⁹ to 5×10²⁰ atoms/cm³.

13. The method of claim 1 wherein the dopant impurity species comprise a boron species derived from B₂H₆.

14. The method of claim 1 wherein the dopant impurity species is of P− type.

15. The method of claim 1 further comprising performing a P+ type implant in the silicon germanium material in the source region and the drain region.

16. The method of claim 1 further comprising performing a rapid thermal anneal of the silicon germanium material in the source region and the drain region at a temperature ranging from about 1000 to about 1200 Celsius.

17. The method of claim 1 wherein the selective epi growth occurs only on exposed crystalline silicon surfaces.

18. The method of claim 1 wherein the doping is provided upon deposition of the silicon germanium species.

19. The method of claim 1 wherein the dopant impurity species is activated upon deposition of the silicon germanium species.

20. The method of claim 1 wherein the silicon germanium material is formed using an SiH₄ bearing species and an GeH₄ being species.

21. The method of claim 20 wherein the SiH₄ bearing species and the GeH₄ bearing species is combined with an HCl species and H₂ species.

22. A method for forming a semiconductor integrated circuit device comprising:
providing a semiconductor substrate;
forming a dielectric layer overlying the semiconductor substrate;
forming a gate layer overlying the dielectric layer;
patterning the gate layer to form a gate structure including edges;
forming a dielectric layer overlying the gate structure to protect the gate structure including the edges;
etching a source region and a drain region adjacent to the gate structure using the dielectric layer as a protective layer;
depositing using selective epi growth of a silicon carbide material into the source region and the drain region to fill the etched source region and the etched drain region;
simultaneously introducing a dopant impurity species into the silicon carbide material during a portion of the time associated with the depositing of the silicon carbide material to dope the silicon germanium material during the portion of the time associated with the depositing of the silicon carbide material; and
causing a channel region between the source region and the drain region to be strained in tensile mode from at least the silicon carbide material formed in the source region and the drain region.

23. The method of claim 22 wherein the dielectric layer has a thickness that is less than 300 Angstroms.

24. The method of claim 22 wherein the channel region has a length of a width of the gate structure.

25. The method of claim 22 wherein the semiconductor substrate is essentially silicon material.

26. The method of claim 22 wherein the silicon carbide material is single crystalline.

27. The method of claim22 further comprising forming a spacer layer overlying the semiconductor substrate including silicon carbide, gate structure, and edges.

28. The method of claim 22 further comprising anisotropic etching the spacer layer to form sidewall spacers on edges of the gate layer.

29. The method of claim 22 wherein the depositing is provided using an epitaxial reactor.

30. The method of claim 22 wherein the tensile mode increases a mobility of electrons in the channel region.

31. The method of claim 22 wherein the dopant impurity species is provided in-situ.

32. The method of claim 22 wherein the dopant impurity species comprise an arsenic bearing impurities.

33. The method of claim 22 wherein the dopant impurity species comprise a phosphorus species.

34. The method of claim 22 wherein the dopant impurities have a concentration ranging from 1×10¹⁹ to 1×10²⁰ atoms/cm³.

35. The method of claim 22 wherein the dopant impurity species is of N-type.

36. The method of claim 22 further comprising performing a N-type implant in the silicon carbide material in the source region and the drain region.

37. The method of claim 22 further comprising performing a rapid thermal anneal of the silicon carbide material in the source region and the drain region at a temperature ranging from about 1000 to about 1200 Celsius.

38. The method of claim 22 wherein the selective epi growth occurs only on exposed crystalline silicon surfaces.

39. The method of claim 22 wherein the doping is provided upon deposition of the silicon carbide species.

40. The method of claim 22 wherein the dopant impurity species is activated upon deposition of the silicon carbide species.

41. A method for forming a semiconductor integrated circuit device comprising
providing a semiconductor substrate, the semiconductor substrate being characterized by a first lattice constant;
forming a dielectric layer overlying the semiconductor substrate;
forming a gate layer overlying the dielectric layer;
patterning the gate layer to form a gate structure including edges;
forming a dielectric layer overlying the gate structure to protect the gate structure including the edges;
etching a source region and a drain region adjacent to the gate structure using the dielectric layer as a protective layer;
depositing using a selective epi growth material into the source region and the drain region to fill the etched source region and the etched drain region;
simultaneously introducing a dopant impurity species into the fill material during a portion of the time associated with the depositing of the fill material to dope the fill material during the portion of the time associated with the depositing of the fill material, the deposited fill material being characterized by a second lattice constant; and
causing a channel region between the source region and the drain region to be strained, the strained channel region being associated with at least a difference between the first lattice constant of the semiconductor substrate and the second lattice constant of the fill material formed in the source region and the drain region.
